(19) United States
(12) Patent Application Publication
(10) Pub. No.: US 2024/0150653 A1
(43) Pub. Date: May 9, 2024

(54) ETCHANT COMPOSITIONS AND RELATED METHODS

(71) Applicant: ENTEGRIS, INC., Billerica, MA (US)

(72) Inventors: Steven M. Bilodeau, Fairfield, CT (US); Claudia Yevenes, White Plains, NY (US)

(21) Appl. No.: 18/376,226

(22) Filed: Oct. 3, 2023

Related U.S. Application Data
(60) Provisional application No. 63/417,611, filed on Oct. 19, 2022.

(51) Int. Cl. C09K 13/06

(52) U.S. Cl. CPC C09K 13/06

(57) ABSTRACT

Etchant compositions for selective etching of silicon nitride in the presence of silicon oxide and polysilicon are provided. The etchant compositions may achieve passivation of at least one of silicon oxide, polysilicon, or any combination thereof, while selectively etching silicon nitride, in a single step by applying the etchant composition to a substrate. The etchant compositions may comprise at least 60% by weight of phosphoric acid based on a total weight of the etchant composition; at least 1% by weight of water based on the total weight of the etchant composition; and no greater than 2% by weight of a metal oxidizer based on the total weight of the etchant composition.

### FIELD

The present disclosure relates to etchant compositions for selective etching and related methods.

### BACKGROUND

Manufacture of microelectronic devices involves material removal via etching. The removal of these materials via etching can also result in the undesirable removal of other materials.

### SUMMARY

Some embodiments relate to an etchant composition. In some embodiments, the etchant composition comprises at least 60% by weight of phosphoric acid based on a total weight of the etchant composition. In some embodiments, the etchant composition comprises at least 3% by weight of water based on the total weight of the etchant composition. In some embodiments, the etchant composition comprises no greater than 2% by weight of a metal oxidizer based on the total weight of the etchant composition.

Some embodiments relate to a method for selective etching of silicon nitride. In some embodiments, the method comprises obtaining a substrate. In some embodiments, the substrate comprises a surface comprising silicon nitride. In some embodiments, the substrate comprises a surface comprising silicon oxide. In some embodiments, the substrate comprises a surface comprising polysilicon. In some embodiments, the method comprises obtaining an etchant composition. In some embodiments, the etchant composition comprises at least 60% by weight of phosphoric acid based on a total weight of the composition. In some embodiments, the etchant composition comprises at least 3% by weight of water based on the total weight of the composition. In some embodiments, the etchant composition comprises no greater than 2% by weight of a metal oxidizer based on the total weight of the composition. In some embodiments, the method comprises contacting the substrate with the etchant composition.

Some embodiments relate to a method for preparing an etchant composition. In some embodiments, the method comprises obtaining at least one of a metal oxidizing agent, phosphoric acid, and water. In some embodiments, the method comprises contacting the metal oxidizing agent, the phosphoric acid, and the water, so as to form an etchant composition. In some embodiments, the etchant composition comprises at least 60% by weight of phosphoric acid based on a total weight of the composition. In some embodiments, the etchant composition comprises at least 3% by weight of water based on the total weight of the composition. In some embodiments, the etchant composition comprises no greater than 2% by weight of a metal oxidizer based on the total weight of the composition.

### BRIEF DESCRIPTION OF THE FIGURES

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method for selective etching of silicon nitride, according to some embodiments.

FIG. 2 is a schematic diagram of a method for selective etching of silicon nitride, according to some embodiments.

FIG. 3 is a flowchart of a method for selective etching of silicon nitride, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may.

Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “alkyl” refers to a hydrocarbon compound having from 1 to 30 carbon atoms. An alkyl having n carbon atoms may be designated as a “Cₙ alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₅-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, dodecyl, octadecyl, or any combination thereof.

As used herein, the term “alkenyl” refers to a hydrocarbon chain radical having from 1 to 10 carbon atoms and at least one carbon-carbon double bond. Examples of alkenyl groups include, without limitation, at least one of vinyl, allyl, 1-methylvinyl, 1-propenyl, 1-butenyl, 2-butenyl, 3-butenyl, 1,3-butadienyl, 2-methyl-1-propenyl, 2-methyl-2-propenyl, 1-pentenyl, 2-pentenyl, 3-pentenyl, 4-pentenyl, 1,3-pentadienyl, 2,4-pentadienyl, 1,4-pentadienyl, 3-methyl-2-butenyl, 1-hexenyl, 2-hexenyl, 3-hexenyl, 1,3-hexadienyl, 1,4-hexadienyl, 2-methylpentenyl, 1-heptenyl, 3-heptenyl, 1-octenyl, 1,3-octadienyl, 1-nonenyl, 2-nonenyl, 3-nonenyl, 1-decenyl, 3-decenyl, 1-undecenyl, oleyl, linoleyl, linolenyl, or any combination thereof.

As used herein, the term “alkynyl” refers to a hydrocarbon chain radical having from 1 to 10 carbon atoms and at least one carbon-carbon triple bond. Examples of alkynyl groups include, without limitation, at least one of ethynyl, propynyl, n-butynyl, n-pentynyl, 3-methyl-1-butynyl, n-hexynyl, methyl-pentynyl, or any combination thereof.

As used herein, the term “alkoxy” refers to a radical of formula —OR, wherein R is an alkyl, as defined herein. In some embodiments, the alkoxy may comprise, consist of, or consist essentially of, or may selected from the group consisting of, at least one of methoxy, ethoxy, methoxy, ethoxy, n-propoxy, 1-methylethoxy (isopropoxy), n-butoxy, iso-butoxy, sec-butoxy, tert-butoxy, or any combination thereof.

As used herein, the term “amine,” “alkylamino,” and the like refer to a radical of formula —N(R^{a}R^{b}R^{c}), wherein each of R^{a}, R^{b}, and R^{c} is independently a hydrogen or an alkyl, as defined herein. In some embodiments, the term “amine” includes an amino, as defined herein. In some embodiments, the amine may comprise, consist of, or consist essentially of a primary amine, a secondary amine, a tertiary amine, or a quaternary amine. In some embodiments, the amine may comprise, consist of, or consist essentially of an alkyl amine, a dialkylamine, or a trialkyl amine. In some embodiments, the amine may comprise, consist of, or consist essentially of, or may be selected from the group consisting of, at least one of methyl amine, dimethylamine, ethylamine, diethylamine, isopropylamine, di-isopropylamine, butylamine, sec-butylamine, tert-butylamine, di-sec-butylamine, isobutylamine, di-isobutylamine, di-tert-pentylamine, ethylmethylamine, isopropyl-n-propylamine, or any combination thereof. Examples of the alkylamines may include, without limitation, one or more of the following: primary alkylamines, such as, for example and without limitation, methylamine, ethylamine, n-propylamine, isopropylamine, n-butylamine, sec-butylamine, isobutylamine, t-butylamine, pentylamine, 2-aminopentane, 3-aminopentane, 1-amino-2-methylbutane, 2-amino-2-methylbutane, 3-amino-2-methylbutane, 4-amino-2-methylbutane, hexylamine, 5-amino-2-methylpentane, heptylamine, octylamine, nonylamine, decylamine, undecylamine, dodecylamine, tridecylamine, tetradecylamine, pentadecylamine, hexadecylamine, heptadecylamine, and octadecylamine; secondary alkylamines, such as, for example and without limitation, dimethylamine, diethylamine, dipropylamine, diisopropylamine, dibutylamine, diisobutylamine, di-sec-butylamine, di-t-butylamine, dipentylamine, dihexylamine, diheptylamine, dioctylamine, dinonylamine, didecylamine, methylethylamine, methylpropylamine, methylisopropylamine, methylbutylamine, methylisobutylamine, methyl-sec-butylamine, methyl-t-butylamine, methylamylamine, methylisoamylamine, ethylpropylamine, ethylisopropylamine, ethylbutylamine, ethylisobutylamine, ethyl-sec-butylamine, ethylamine, ethylisoamylamine, propylbutylamine, and propylisobutylamine; and tertiary alkylamines, such as, for example and without limitation, trimethylamine, triethylamine, tripropylamine, tributylamine, tripentylamine, dimethylethylamine, methyldiethylamine, and methyldipropylamine. Examples of polyamines may include, without limitation, one or more of the following: ethylenediamine, propylenediamine, trimethylenediamine, tetramethylenediamine, 1,3-diaminobutane, 2,3-diaminobutane, pentamethylenediamine, 2,4-diaminopentane, hexamethylenediamine, heptamethylenediamine, octamethylenediamine, nonamethylenediamine, N-methylethylenediamine, N,N-dimethylethylenediamine, trimethylethylenediamine, N-ethylethylenediamine, N,N-diethylethylenediamine, triethylethylenediamine, 1,2,3-triaminopropane, hydrazine, tris(2-aminoethyl)amine, tetra(aminomethyl)methane, diethylenetriamine, triethylenetetramine, tetraethylpentamine, heptaethyleneoctamine, nonaethylenedecamine, and diazabicyloundecene.

As used herein, the term “cycloalkyl” refers to a non-aromatic carbocyclic ring radical attached via a single bond and having from 3 to 8 carbon atoms in the ring. The term includes a monocyclic non-aromatic carbocyclic ring and a polycyclic non-aromatic carbocyclic ring. For example, two or more cycloalkyls may be fused, bridged, or fused and bridged to obtain the polycyclic non-aromatic carbocyclic ring. In some embodiments, the cycloalkyl may comprise, consist of, or consist essentially of, or may be selected from the group consisting of, at least one of cyclopropyl, cyclobutyl, cyclopentyl, cyclohexyl, cycloheptyl, cyclooctyl, or any combination thereof.

As used herein, the term “aryl” refers to a monocyclic or polycyclic aromatic hydrocarbon compound. The number of carbon atoms of the aryl may be in a range of 5 carbon atoms to 100 carbon atoms. In some embodiments, the aryl has 5 to 20 carbon atoms. For example, in some embodiments, the aryl has 6 to 8 carbon atoms, 6 to 10 carbon atoms, 6 to 12 carbon atoms, 6 to 15 carbon atoms, or 6 to 20 carbon atoms. The term “monocyclic,” when used as a modifier, refers to an aryl having a single aromatic ring structure. The term “polycyclic,” when used as a modifier, refers to an aryl having more than one aromatic ring structure, which may be fused, bridged, spiro, or otherwise bonded ring structures. Examples of aryls include, without limitation, phenyl, biphenyl, napthyl, and the like. In some embodiments, at least one carbon atom of the aryl—for example, in the aromatic ring structure—is substituted for a heteroatom, including, for example and without limitation, at least one of O, N, etc.

As used herein, the term “microelectronic device” (or “microelectronic device substrate,” or simply “substrate”) is used in a manner that is consistent with the generally understood meaning of this term in the electronics, microelectronics, and semiconductor fabrication arts, for example to refer to any of a variety of different types of: semiconductor substrates; integrated circuits; solid state memory devices; hard memory disks; read, write, and read-write heads and mechanical or electronic components thereof; flat panel displays; phase change memory devices; solar panels and other products that include one or more solar cell devices; photovoltaics; and microelectromechanical systems (MEMS) manufactured for use in microelectronic, integrated circuit, energy collection, or computer chip applications. It is to be understood that the term “microelectronic device” can refer to any in-process microelectronic device or microelectronic device substrate that contains or is being prepared to contain functional electronic (electrical-current-carrying) structures, functional semiconductor structures, and insulating structures, for eventual electronic use in a microelectronic device or microelectronic assembly.

As used herein, the term “silicon nitride” is given a meaning that is consistent with the meaning of the term as used in the microelectronics and semiconductor fabrication industries. Consistent therewith, silicon nitride refers to materials including thin films made of amorphous silicon nitride with commercially useful low levels of other materials or impurities and potentially some variation around the nominal stoichiometry of Si₃N₄. The silicon nitride may be present as part of a microelectronic device substrate as a functioning feature of the device, for example as a barrier layer or an insulating layer, or may be present to function as a material that facilitates a multi-step fabrication method for preparing a microelectronic device.

As used herein, the term “silicon oxide” is given a meaning that is consistent with the meaning of the term as used in the microelectronics and semiconductor fabrication industries. Consistent therewith, silicon oxide refers to thin films made of silicon oxide (SiOx), e.g., SiO₂, “thermal oxide” (ThOx), and the like. The silicon oxide can be placed on the substrate by any method, such as by being deposited by chemical vapor deposition from tetraethoxysilane (TEOS) or another source, or by being thermally deposited. The silicon oxide can advantageously contain a commercially useful low level of other materials or impurities. The silicon oxide may be present as part of a microelectronic device substrate as a feature of the microelectronic device, for example, as an insulating layer.

As used herein, the term “polysilicon” or polycrystalline Si or poly-Si is understood by the person skilled in the art to be a polycrystalline form of silicon comprising multiple small silicon crystals. It is typically deposited using low-pressure chemical vapor deposition (LPCVD) and is often doped n-type polysilicon or p-type polysilicon. The extent of doping can vary from lightly doped (e.g., in a range from 1013 cm⁻³ to 1018 cm⁻³) to heavily doped (e.g., greater than 1018 cm⁻³), as readily understood by the person skilled in the art. Examples of p-doped material include polysilicon doped with a dopant species from Group IIIA of the Periodic Table, such as at least one of boron, aluminum, gallium, indium, or any combination thereof. An n-doped material may for example be polysilicon doped with a dopant species from Group IV (silicon, germanium, or tin) or Group V (phosphorus, arsenic, antimony, or bismuth) of the Periodic Table.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Manufacture of microelectronic devices and fabrication of semiconductors can involve material removal via etching. Silicon nitride is an example of a material removed during the manufacture of microelectronic devices. For example, silicon nitride can be deposited as a thin layer on a substrate, optionally as a patterned thin layer, by chemical vapor deposition. During the manufacture or fabrication process, the silicon nitride layer is to be at least partially removed. Etchants may be useful for removing at least a portion of the silicon nitride layer. Current etchants, however, remove or otherwise damage other materials present, such as, for example and without limitation, silicon oxide and polysilicon, in addition to removing silicon nitride. The removal of or damage caused to these other materials—including silicon oxide and polysilicon—is undesirable.

Some embodiments relate to etchant compositions useful in the manufacture of microelectronics, including the fabrication of semiconductors. The etchant compositions disclosed herein exhibit a high selectivity for silicon nitride, over other materials, including silicon oxide and polysilicon. That is, for example, the etchant compositions disclosed herein are capable of removing silicon nitride without removing or otherwise damaging layers or surfaces comprising at least one of silicon oxide, polysilicon, or any combination thereof. The etchant compositions may also exhibit a dual functionality in a single application. That is, for example, a single application of the etchant compositions disclosed herein is capable of passivating the polysilicon, while also etching the silicon nitride with a sufficiently high etch rate, and while preserving the silicon oxide. In other words, the process of passivating and etching is capable of being achieved in a single step of a process. These and other advantages will become apparent from the disclosure herein.

The etchant compositions disclosed herein may comprise one or more components. In some embodiments, the etchant composition is a result of a combination of the one or more components. In some embodiments, the etchant composition is a composition comprising the one or more components. In some embodiments, the etchant composition is a mixture of the one or more components. In some embodiments, an etchant composition is derived from a formulation. In some embodiments, the etchant composition is a reaction product of a formulation, wherein the formulation comprises the one or more components which undergo a reaction. In some embodiments, the etchant composition is a dissolution product of a formulation, wherein the formulation comprises the one or more components which undergo dissolution or solubilization (e.g., dissolving). In some embodiments, the formulation comprises one or more components which are inert, wherein the one or more inert components do not undergo any physical or chemical change.

The etchant compositions may comprise a solution. In some embodiments, the etchant composition comprises a liquid solution. In some embodiments, the etchant composition comprises a liquid solution and at least one solid component.

In some embodiments, the etchant composition comprises a slurry. In some embodiments, the etchant composition comprises a suspension. In some embodiments, the etchant composition comprises an emulsion. In some embodiments, the etchant composition comprises a solution of at least one dissolved component. In some embodiments, the etchant composition comprises any combination of the foregoing.

In some embodiments, the one or more components may comprise a metal oxidizing agent. In some embodiments, the metal oxidizing agent comprises at least one of the following metals: Sc, Ti, V, Cr, Mn, Fe, Co, Ni, Cu, Zn, Y, Zr, Nb, Mo, Tc, Ru, Rh, Pd, Ag, Cd, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Ac, Th, Pa, U, Np, Pu, Am, Cm, Bk, Cf, Es, Fm, Md, No, Lr, Rf, Db, Sg, Bh, Hs, Mt, Ds, Rg, Cn, or any combination thereof. In some embodiments, the metal oxidizing agent comprises at least one of a metal sulfate, a metal oxysulfate, a metal oxide, a metal phosphate, a metal dihydrogen phosphate, a metal halide, a metal hydroxide, a metal acid, a metal nitrate, a metal ammonium nitrate, a metal carbonate, any hydrate thereof, or any combination thereof. Examples of the metal oxidizing agent include, without limitation, at least one of titanium (IV) oxysulfate, titanium (IV) sulfate hydrate, phosphomolybdic acid hydrate, silicomolybdic acid, molybdenum (VI) oxide, molybdic acid, lanthanum oxide, cerium (IV) sulfate, ceric ammonium nitrate, phosphotungstic acid, vanadium pentaoxide, cobalt (Ill) acetylacetonate, or any combination thereof.

The metal oxidizing agent may be present in the etchant composition as a dissolution product. For example, in some embodiments, the metal oxidizing agent dissociates in the etchant composition into a metal oxidizer. In some embodiments, the metal oxidizing agent dissociates into a metal cation and an anion. In some embodiments, the metal oxidizer comprises a metal cation of at least one of the following metals: Sc, Ti, V, Cr, Mn, Fe, Co, Ni, Cu, Zn, Y, Zr, Nb, Mo, Tc, Ru, Rh, Pd, Ag, Cd, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Ac, Th, Pa, U, Np, Pu, Am, Cm, Bk, Cf, Es, Fm, Md, No, Lr, Rf, Db, Sg, Bh, Hs, Mt, Ds, Rg, Cn, or any combination thereof. In some embodiments, the metal oxidizer comprises a metal cation in the highest oxidization state. In some embodiments, the metal oxidizer comprises a metal cation which is not in the highest oxidation state. Examples of the metal oxidizer include, without limitation, at least one of the following: Ti⁺³, Ti⁺⁴, V⁺², V⁺³, V⁺⁴, V⁺⁵, Co⁺², Co⁺³, Ni⁺², Ni⁺³, Ni⁺⁴, Mo⁺, Mo⁺², Mo⁺³, Mo⁺⁴, Mo⁺⁵, Mo⁺⁶, Ce⁺, Ce⁺², Ce⁺³, Ce⁺⁴, W⁺⁶, Pt⁺⁴, Rh⁺, Rh⁺², Rh⁺³, Rh⁺⁴, Rh⁺⁵, Gd⁺³, or any combination thereof.

The etchant composition may comprise 0.001% to 2% by weight of the metal oxidizing agent based on a total weight of the etchant composition, or any range or subrange between 0.001% and 2%. For example, in some embodiments, the etchant composition comprises 0.02% to 2%, 0.03% to 2%, 0.04% to 2%, 0.05% to 2%, 0.06% to 2%, 0.07% to 2%, 0.08% to 2%, 0.09% to 2%, 0.1% to 2%, 0.2% to 2%, 0.3% to 2%, 0.4% to 2%, 0.5% to 2%, 0.6% to 2%, 0.7% to 2%, 0.8% to 2%, 0.9% to 2%, 1% to 2%, 1.1% to 2%, 1.2% to 2%, 1.3% to 2%, 1.4% to 2%, 1.5% to 2%, 1.6% to 2%, 1.7% to 2%, 1.8% to 2%, 1.9% to 2%, 0.01% to 1.9%, 0.01% to 1.8%, 0.01% to 1.7%, 0.01% to 1.6%, 0.01% to 1.5%, 0.01% to 1.4%, 0.01% to 1.3%, 0.01% to 1.2%, 0.01% to 1.1%, 0.01% to 1%, 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, 0.01% to 0.1%, 0.01% to 0.09%, 0.01% to 0.08%, 0.01% to 0.07%, 0.01% to 0.06%, 0.01% to 0.05%, 0.01% to 0.04%, 0.01% to 0.03%, or 0.01% to 0.02%, by weight of the metal oxidizing agent based on a total weight of the etchant composition. In some embodiments, the weight percentage is based on a total weight of the formulation.

The etchant composition may comprise 0.01% to 0.5% by weight of the metal oxidizing agent based on a total weight of the etchant composition, or any range or subrange between 0.01% and 0.5%. In some embodiments, the etchant composition comprises 0.01% to 0.5%, 0.01% to 0.45%, 0.01% to 0.4%, 0.01% to 0.35%, 0.01% to 0.3%, 0.01% to 0.25%, 0.01% to 0.2%, 0.01% to 0.15%, 0.01% to 0.1%, 0.01% to 0.05%, 0.02% to 0.5%, 0.03% to 0.5%, 0.04% to 0.5%, 0.05% to 0.5%, 0.06% to 0.5%, 0.07% to 0.5%, 0.08% to 0.5%, 0.09% to 0.5%, 0.1% to 0.5%, 0.15% to 0.5%, 0.2% to 0.5%, 0.25% to 0.5%, 0.3% to 0.5%, 0.35% to 0.5%, 0.4% to 0.5%, or 0.45% to 0.5%, by weight of the metal oxidizing agent based on the total weight of the etchant composition. In some embodiments, the weight percentage is based on a total weight of the formulation.

The etchant composition may comprise no greater than 2% by weight of the metal oxidizer based on the total weight of the etchant composition. For example, in some embodiments, the etchant composition comprises no greater than 1.9%, no greater than 1.8%, no greater than 1.7%, no greater than 1.6%, no greater than 1.5%, no greater than 1.4%, no greater than 1.3%, no greater than 1.2%, no greater than 1.1%, no greater than 1%, no greater than 0.9%, no greater than 0.8%, no greater than 0.7%, no greater than 0.6%, no greater than 0.5%, no greater than 0.4%, no greater than 0.3%, no greater than 0.2%, no greater than 0.1%, no greater than 0.09%, no greater than 0.08%, no greater than 0.07%, no greater than 0.06%, no greater than 0.05%, no greater than 0.04%, no greater than 0.03%, no greater than 0.02%, no greater than 0.01%, no greater than 0.009%, no greater than 0.008%, no greater than 0.007%, no greater than 0.006%, no greater than 0.005%, no greater than 0.004%, no greater than 0.003%, no greater than 0.002% by weight of the metal oxidizer based on the total weight of the etchant composition.

The etchant composition may comprise 0.001% to 2% by weight of the metal oxidizer based on a total weight of the etchant composition, or any range or subrange between 0.001% and 2%. For example, in some embodiments, the etchant composition comprises 0.001% to 1%, 0.02% to 2%, 0.03% to 2%, 0.04% to 2%, 0.05% to 2%, 0.06% to 2%, 0.07% to 2%, 0.08% to 2%, 0.09% to 2%, 0.1% to 2%, 0.2% to 2%, 0.3% to 2%, 0.4% to 2%, 0.5% to 2%, 0.6% to 2%, 0.7% to 2%, 0.8% to 2%, 0.9% to 2%, 1% to 2%, 1.1% to 2%, 1.2% to 2%, 1.3% to 2%, 1.4% to 2%, 1.5% to 2%, 1.6% to 2%, 1.7% to 2%, 1.8% to 2%, 1.9% to 2%, 0.01% to 1.9%, 0.01% to 1.8%, 0.01% to 1.7%, 0.01% to 1.6%, 0.01% to 1.5%, 0.01% to 1.4%, 0.01% to 1.3%, 0.01% to 1.2%, 0.01% to 1.1%, 0.01% to 1%, 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, 0.01% to 0.1%, 0.01% to 0.09%, 0.01% to 0.08%, 0.01% to 0.07%, 0.01% to 0.06%, 0.01% to 0.05%, 0.01% to 0.04%, 0.01% to 0.03%, or 0.01% to 0.02%, by weight of the metal oxidizer based on a total weight of the etchant composition. In some embodiments, the weight percentage is based on a total weight of the formulation.

The etchant composition may comprise 0.01% to 0.5% by weight of the metal oxidizer based on a total weight of the etchant composition, or any range or subrange between 0.01% and 0.5%. In some embodiments, the etchant composition comprises 0.01% to 0.5%, 0.01% to 0.45%, 0.01% to 0.4%, 0.01% to 0.35%, 0.01% to 0.3%, 0.01% to 0.25%, 0.01% to 0.2%, 0.01% to 0.15%, 0.01% to 0.1%, 0.01% to 0.05%, 0.02% to 0.5%, 0.03% to 0.5%, 0.04% to 0.5%, 0.05% to 0.5%, 0.06% to 0.5%, 0.07% to 0.5%, 0.08% to 0.5%, 0.09% to 0.5%, 0.1% to 0.5%, 0.15% to 0.5%, 0.2% to 0.5%, 0.25% to 0.5%, 0.3% to 0.5%, 0.35% to 0.5%, 0.4% to 0.5%, or 0.45% to 0.5%, by weight of the metal oxidizer based on the total weight of the etchant composition. In some embodiments, the weight percentage is based on a total weight of the formulation.

The etchant composition may comprise 0.001% to 2% by weight of the metal oxidizer based on a total weight of the etchant composition, or any range or subrange between 0.001% and 2%. For example, in some embodiments, the etchant composition comprises 0.02% to 2%, 0.03% to 2%, 0.04% to 2%, 0.05% to 2%, 0.06% to 2%, 0.07% to 2%, 0.08% to 2%, 0.09% to 2%, 0.1% to 2%, 0.2% to 2%, 0.3% to 2%, 0.4% to 2%, 0.5% to 2%, 0.6% to 2%, 0.7% to 2%, 0.8% to 2%, 0.9% to 2%, 1% to 2%, 1.1% to 2%, 1.2% to 2%, 1.3% to 2%, 1.4% to 2%, 1.5% to 2%, 1.6% to 2%, 1.7% to 2%, 1.8% to 2%, 1.9% to 2%, 0.01% to 1.9%, 0.01% to 1.8%, 0.01% to 1.7%, 0.01% to 1.6%, 0.01% to 1.5%, 0.01% to 1.4%, 0.01% to 1.3%, 0.01% to 1.2%, 0.01% to 1.1%, 0.01% to 1%, 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, 0.01% to 0.1%, 0.01% to 0.09%, 0.01% to 0.08%, 0.01% to 0.07%, 0.01% to 0.06%, 0.01% to 0.05%, 0.01% to 0.04%, 0.01% to 0.03%, or 0.01% to 0.02%, by weight of the metal oxidizing agent based on a total weight of the etchant composition. In some embodiments, the weight percentage is based on a total weight of the formulation.

The etchant composition may comprise 0.001% to 0.5% by weight of the metal oxidizer based on a total weight of the etchant composition, or any range or subrange between 0.001% and 0.5%. In some embodiments, the etchant composition comprises 0.002% to 0.5%, 0.004% to 0.5%, 0.005% to 0.5%, 0.006% to 0.5%, 0.008% to 0.5%, 0.01% to 0.5%, 0.01% to 0.45%, 0.01% to 0.4%, 0.01% to 0.35%, 0.01% to 0.3%, 0.01% to 0.25%, 0.01% to 0.2%, 0.01% to 0.15%, 0.01% to 0.1%, 0.001% to 0.05%, 0.002% to 0.5%, 0.003% to 0.5%, 0.004% to 0.5%, 0.005% to 0.5%, 0.006% to 0.5%, 0.007% to 0.5%, 0.008% to 0.5%, 0.009% to 0.5%, 0.01% to 0.05%, 0.02% to 0.5%, 0.03% to 0.5%, 0.04% to 0.5%, 0.05% to 0.5%, 0.06% to 0.5%, 0.07% to 0.5%, 0.08% to 0.5%, 0.09% to 0.5%, 0.1% to 0.5%, 0.15% to 0.5%, 0.2% to 0.5%, 0.25% to 0.5%, 0.3% to 0.5%, 0.35% to 0.5%, 0.4% to 0.5%, or 0.45% to 0.5%, by weight of the metal oxidizer based on the total weight of the etchant composition. In some embodiments, the weight percentage is based on a total weight of the formulation.

In some embodiments, the one or more components may comprise phosphoric acid or any derivative thereof. In some embodiments, the phosphoric acid is an active component for etching silicon nitride. In some embodiments, the phosphoric acid comprises phosphoric acid solids. In some embodiments, the phosphoric acid is provided in an aqueous phosphoric acid solution. In some embodiments, the aqueous phosphoric acid solution comprises at least one of phosphoric acid solids, water, at least one additional component, or any combination thereof. In some embodiments, the aqueous phosphoric acid solution comprises 50% to 99% by weight of phosphoric acid based on a total weight of the aqueous phosphoric acid solution, or any range or subrange therebetween. In some embodiments, the aqueous phosphoric acid solution comprises 80% to 90% by weight of phosphoric acid based on a total weight of the aqueous phosphoric acid solution. In some embodiments, the aqueous phosphoric acid solution comprises 80% to 85% by weight of phosphoric acid based on a total weight of the aqueous phosphoric acid solution. In some embodiments, the balance of the aqueous phosphoric acid solution comprises water or the at least one additional component.

The etchant composition may comprise at least 50% by weight of phosphoric acid based on the total weight of the etchant composition. For example, in some embodiments, the etchant composition comprises at least 60%, at least 65%, at least 70%, at least 75%, at least 80%, at least 85%, at least 90%, or at least 95% by weight of phosphoric acid based on the total weight of the etchant composition.

In some embodiments, the etchant composition comprises 50% to 99%, 55% to 99%, 60% to 99%, 65% to 99%, 70% to 99%, 75% to 99%, 80% to 99%, 85% to 99%, 90% to 99%, 95% to 99%, 50% to 95%, 50% to 90%, 50% to 85%, 50% to 80%, 50% to 75%, 50% to 70%, 50% to 65%, 50% to 60%, 50% to 55%, 70% to 95%, 75% to 95%, 80% to 95%, 85% to 95%, 90% to 95%, 70% to 90%, 70% to 85%, 70% to 80%, 75% to 90%, 75% to 85%, 80% to 90%, or 85% to 90% by weight of phosphoric acid based on the total weight of the etchant composition.

In some embodiments, the one or more components may comprise water or any derivative thereof. In some embodiments, the water is added to modulate selectivity for silicon nitride, increase an etch rate of the silicon nitride, or any combination thereof. The etchant composition may comprise at least 5% by weight of water based on the total weight of the etchant composition. For example, in some embodiments, the etchant composition comprises at least 1%, at least 3%, at least 5%, at least 10%, at least 15%, at least 20%, at least 25%, at least 30%, at least 35%, at least 40%, at least 40% by weight of water based on the total weight of the etchant composition. In some embodiments, the etchant composition comprises no greater than 50% by weight of water based on the total weight of the etchant composition. For example, in some embodiments, the etchant composition comprises no greater than 45%, no greater than 40%, no greater than 35%, no greater than 30%, no greater than 25%, no greater than 20%, no greater than 15%, no greater than 10%, or no greater than 5% by weight of water based on the total weight of the etchant composition.

The etchant composition may comprise 1% to 50% by weight of the water based on the total weight of the etchant composition, or any range or subrange between 1% to 50%. For example, in some embodiments, the etchant composition comprises 1% to 45%, 1% to 40%, 1% to 35%, 1% to 30%, 1% to 25%, 1% to 20%, 1% to 15%, 1% to 10%, 1% to 5%, 5% to 45%, 5% to 40%, 5% to 35%, 5% to 30%, 5% to 25%, 5% to 20%, 5% to 15%, 5% to 10%, 10% to 50%, 15% to 50%, 20% to 50%, 25% to 50%, 30% to 50%, 35% to 50%, 40% to 50%, 45% to 50%, 5% to 25%, 6% to 25%, 8% to 25%, 10% to 25%, 12% to 25%, 14% to 25%, 15% to 25%, 16% to 25%, 18% to 25%, 20% to 25%, 22% to 25%, 24% to 25%, 5% to 24%, 5% to 22%, 5% to 18% 5% to 16%, 5% to 14%, 5% to by weight of the water based on a total weight of the etchant composition.

In some embodiments, the one or more components may comprise a fluoride compound or any derivative thereof. In some embodiments, the fluoride compound is added to modulate selectivity for silicon nitride, increase an etch rate of the silicon nitride, or any combination thereof. In some embodiments, the fluoride compound comprises at least one of hydrogen fluoride (HF), ammonium fluoride, tetrafluoroboric acid, hexafluorosilicic acid, a compound comprising a boron-fluoride bond, a compound comprising a silicon-fluoride bond, tetrabutylammonium tetrafluoroborate (TBA-BF₄), tetraalkylammonium fluorides, or any combination thereof.

The etchant composition may comprise 0.0005% (5 ppm) to 5% by weight of the fluoride compound based on the total weight of the etchant composition. For example, in some embodiments, the etchant composition comprises 0.0005% to 0.2%, 0.0006% to 0.2%, 0.0008% to 0.2%, 0.001% to 0.2%, 0.002% (20 ppm) to 0.2%, 0.004% to 0.2%, 0.006% to 0.2%, 0.008% to 0.2%, 0.01% to 0.2%, 0.02% to 0.2%, 0.0% to 0.2%, 0.05% to 0.2%, 0.06% to 0.2%, 0.08% to 0.2%, 0.1% to 0.2%, 0.12% to 0.2%, 0.14% to 0.2%, 0.15% to 0.2%, 0.16% to 0.2%, 0.18% to 0.2%, 0.0005% to 4.5%, 0.0005% to 4%, 0.0005% to 3.5%, 0.0005% to 3%, 0.0005% to 2.5%, 0.0005% to 2%, 0.0005% to 1.5%, 0.0005% to 1%, 0.0005% to 0.5%, 0.0005% to 0.4%, 0.0005% to 0.3%, 0.0005% to 0.2%, 0.0005% to 1%, 0.0005% to 0.9%, 0.0005% to 0.8%, 0.0005% to 0.6%, 0.0005% to 0.5%, 0.0005% to 0.4%, 0.0005% to 0.2%, 0.0005% to 0.1%, 0.0005% to 0.05%, 0.0005% to 0.01%, 0.0005% to 0.005%, 0.0005% to 0.001%, or 0.0005% to 0.0009%.

In some embodiments, the etchant composition does not comprise the fluoride compound. In some embodiments, the etchant composition does not comprise a detectable amount of the fluoride compound.

In some embodiments, the one or more components may comprise silicon-containing compound or any derivative thereof. In some embodiments, the silicon-containing compound is added to modulate the selectivity of the etchant composition for silicon nitride, increase an etch rate of the etchant composition with respect to silicon nitride, or any combination thereof. In some embodiments, the silicon-containing compound dissolves in the etchant composition, reacts with phosphoric acid so as to form a dissolved silicon-containing compound in the etchant composition, or any combination thereof. In some embodiments, the silicon-containing compound comprises at least one of silica; tetramethylammonium silicate (TMAS); tetraacetoxysilane; tetraalkoxysilane; tetramethylammonium silicate; N-(3-trimethoxysilylpropyl) diethylenetriamine; N-(2-aminoethyl)-3-aminopropyltriethoxy silane; N-(2-aminoethyl)-3-aminopropyl silane triol; N-(3-trimethoxysilylpropyl) diethylenetriamine; N-(6-aminohexyl)aminopropyltrimethoxysilane; (3-aminopropyl) triethoxy silane; (3-aminopropyl) silane triol; 3-aminopropylsilanetriol; tetramethoxysilane; tetraethoxysilane; any phosphate ester thereof; or any combination thereof. The amount of the silicon-containing compound added to the etchant composition may include an amount that does not result in supersaturation of the silicon-containing compound at etching conditions.

The etchant composition may comprise 0.0005% (5 ppm) to 1% by weight of the silicon-containing compound based on the total weight of the etchant composition. For example, in some embodiments, the etchant composition comprises 0.0006% to 1%, 0.0008% to 1%, 0.001% to 1%, 0.002% to 1%, 0.004% to 1%, 0.005% to 1%, 0.006% to 1%, 0.008% to 1%, 0.01% to 1%, 0.02% to 1%, 0.04% to 1%, 0.05% to 1%, 0.06% to 1%, 0.08% to 1%, 0.1% to 1%, 0.2% to 1%, 0.4% to 1%, 0.5% to 1%, 0.6% to 1%, 0.8% to 1%, 0.0005% to 0.8%, 0.0005% to 0.6%, 0.0005% to 0.5%, 0.0005% to 0.4%, 0.0005% to 0.2%, 0.0005% to 0.1%, 0.0005% to 0.08%, 0.0005% to 0.06%, 0.0005% to 0.05%, 0.0005% to 0.04%, 0.0005% to 0.02%, 0.0005% to 0.01%, 0.0005% to 0.008%, 0.0005% to 0.006%, 0.0005% to 0.005%, 0.0005% to 0.004%, 0.0005% to 0.002%, 0.0005% to 0.001%, or 0.0005% to 0.0008% of the silicon-containing compound based on the total weight of the etchant composition.

The etchant composition may comprise 0.1% to 10% by weight of the silicon-containing compound based on the total weight of the etchant composition. For example, in some embodiments, the etchant composition comprises 0.1% to 9%, 0.1% to 8%, 0.1% to 7%, 0.1% to 6%, 0.1% to 5%, 0.1% to 4%, 0.1% to 3%, 0.1% to 2%, 0.1% to 1%, 0.5% to 10%, 1% to 10%, 2% to 10%, 3% to 10%, 4% to 10%, 5% to 10%, 6% to 10%, 7% to 10%, 8% to 10%, 9% to 10%, or any combination thereof.

In some embodiments, the one or more components may comprise a compound of the formula:

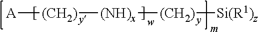

or any derivative thereof,
where:
A is an aryl;

each R¹ is independently a hydrogen, a hydroxyl, a hydroxy, an alkyl, an alkylamino, a phenyl, a benzyl, an alkoxy, a phenoxy, or a cycloalkyl;
x is 0 or 1;
y is 0 or 1 to 5;
y′ is 0 or 1 to 5;
z is 1 to 3;
m is 1 to 3;
w is 0 or 1-4.

In some embodiments, each R¹ is independently a hydrogen, a hydroxyl, a hydroxy, a C₁-C₂₀ alkyl, a C₁-C₂₀ alkylamino, a phenyl, a benzyl, a C₁-C₂₀ alkoxy, a phenoxy, or a C₃-C₈ cycloalkyl.

In some embodiments, each R¹ is the same. In some embodiments, at least one R¹ is different. In some embodiments, each R¹ is different.

In some embodiments, y and y′ are the same. In some embodiments, y and y′ are different.

In some embodiments, m+z is equal to 4.

In some embodiments, the one or more components may comprise a compound of the formula:

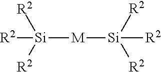

or any derivative thereof,
where:
each R² is independently a hydrogen, a hydroxyl, a hydroxy, an alkyl, an alkylamino, a phenyl, a benzyl, an alkoxy, a phenoxy, or a cycloalkyl;
-M- is —NH— or —O—.

In some embodiments, each R² is independently a hydrogen, a hydroxyl, a hydroxy, a C₁-C₂₀ alkyl, a C₁-C₂₀ alkylamino, a phenyl, a benzyl, a C₁-C₂₀ alkoxy, a phenoxy, or a C₃-C₈ cycloalkyl.

In some embodiments, each R² is the same. In some embodiments, at least one R² is different. In some embodiments, each R² is different.

In some embodiments, the one or more components comprise a compound of the formula:

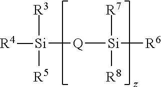

or any derivative thereof,
where:
Q is O or N;
R³ to R⁸ is each independently a hydrogen, an alkyl, an alkoxy, an alkenyl, a cycloalkyl, an aminoalkyl, an aryl, an alkylcarbonyl, an alkylcarbonyloxy, or a cyanoalkyl;
z is 0 or 1, provided that at least two of R³ to R⁷ are an alkoxy when z is 0.

In some embodiments, R³ to R⁸ is each independently a hydrogen, a C₁-C₂₀ alkyl, a C₁-C₂₀ alkoxy, a C₂-C₂₀ alkenyl, a C₃-C₂₀ cycloalkyl, a C₁-C₂₀ aminoalkyl, a C₆-C₂₀ aryl, a C₁-C₂₀ alkylcarbonyl, a C₁-C₂₀ alkylcarbonyloxy, or a C₁-C₁₀ cyanoalkyl.

In some embodiments, the one or more components may comprise at least one of an alkylbenzenesulfonic acid; an alkyldiphenyl oxide disulfonic acid; a compound of the formula Si[phenyl-(—CH₂—)ₓ]ₙ(OR)ₘ, wherein n is 1 to 3, m is 1 to 3, x is 0 or 1 to 3, m+n=4, and each R is independently a hydrogen or an alkyl; a compound of formula:

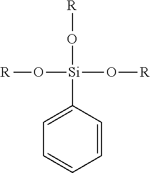

or any derivative thereof,
where:
R is an alkyl (e.g., a C₁-C₄ alkyl); or any combination thereof. The alkylbenzenesulfonic acid may be linear or branched. The alkyldiphenyl oxide disulfonic acid may be a C₅-C₁₆ alkylbenzenesulfonic acid. The alkyldiphenyl oxide disulfonic acid may be a C₆-C₁₂ alkyldiphenyl oxide disulfonic acid. In some embodiments, the one or more components comprise at least one of dodecylbenzenesulfonic acid, 4-octylbenzenesulfonic acid, hexyl diphenyl oxide disulfonic acid, tetrapropyl-(sulfophenoxy)-benzenesulfonic acid, or any combination thereof.

In some embodiments, the one or more components may comprise a pyridine compound or any derivative thereof. In some embodiments, the pyridine compound comprises 4-(3-phenylpropyl)pyridine.

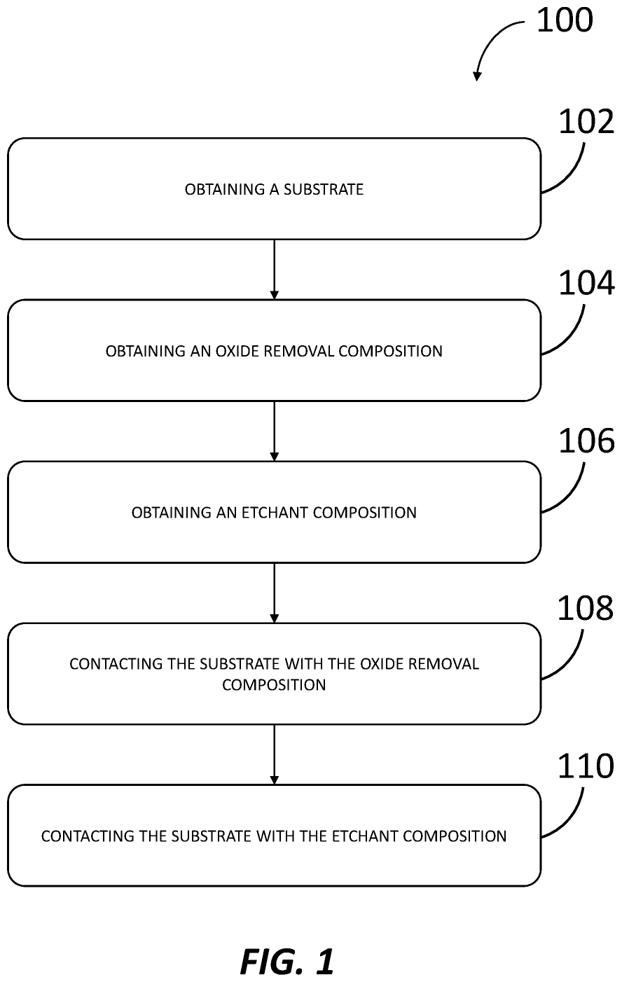

FIG. 1 is a flowchart of a method 100 for selectively etching silicon nitride, according to some embodiments. As shown in FIG. 1, in some embodiments, the methods 100 may comprise at least one of the following steps: a step 102 of obtaining a substrate; a step 104 of obtaining an oxide removal composition; a step 106 of obtaining an etchant composition; a step 108 of contacting the substrate with an oxide removal composition, a step 110 of contacting the substrate with the etchant composition; or any combination thereof.

At step 102, in some embodiments, a substrate is obtained. The substrate may comprise at least one of silicon nitride, silicon oxide, polysilicon, or any combination thereof. In some embodiments, the substrate comprises a surface comprising silicon nitride. In some embodiments, the substrate comprises a surface comprising silicon oxide. In some embodiments, the substrate comprises a surface comprising polysilicon. The substrate may comprise other materials, including surfaces comprising other materials. The substrate can contain other materials that are useful in a microelectronic device, such as one or more of an insulating material, barrier layer, conducting material, semiconducting material, a metal silicide, or a material that is useful for processing a microelectronic device (e.g., photoresist, mask, among others). Examples of substrates include those having a surface that includes at least one of silicon nitride, thermal oxide (ThOx), PETEOS (oxide deposited using plasma enhanced tetraethyl ortho silicate), polysilicon, or any combination thereof.

In some embodiments, the substrate comprises alternating thin film layers of silicon nitride. In some embodiments, the substrate comprises layers of silicon nitride layers alternating with at least one of layers of silicon oxide, layers of polysilicon, layers of conductive metal silicides, layers of dielectrics (e.g., such as zirconium oxide or aluminum oxide), or any combination thereof. Prior to the contacting with the etchant composition, the substrate comprises the alternating layers of silicon nitride positioned in openings between high aspect ratio silicon oxide structures.

At step 104, in some embodiments, an oxide removal composition is obtained. The oxide removal composition may comprise hydrogen fluoride (HF). In some embodiments, the hydrogen fluoride is present in a dilute hydrogen fluoride solution.

At step 106, in some embodiments, an etchant composition is obtained. Any of the etchant compositions disclosed herein may be used. For example, in some embodiments, the etchant composition comprises at least 60% by weight of phosphoric acid based on a total weight of the composition; at least 5% by weight of water based on the total weight of the composition; and no greater than 2% by weight of a metal oxidizer based on the total weight of the composition. It will be appreciated that other etchant compositions disclosed herein may be used without departing from this disclosure.

At step 108, in some embodiments, the substrate is contacted with the oxide removal composition. The oxide removal composition may be useful for removing surface oxides from the substrate and in particular from the silicon nitride surface. That is, in some embodiments, a thin oxidized surface is present on a silicon nitride surface or film. The presence of surface oxides may reduce a rate of etching of the silicon nitride. Accordingly, in some embodiments, the substrate is contacted with the oxide removal composition. As mentioned above, in some embodiments, the oxide removal composition comprises hydrogen fluoride. In some embodiments, the oxide removal composition comprises dilute hydrogen fluoride. After contacting the substrate with the oxide removal composition, excess oxide removal composition and other substances may be rinsed, washed, or otherwise removed from the surfaces using water (e.g., deionized water) at a temperature in a range of 20° C. to 90° C., or any range or subrange therebetween, followed by drying (e.g., spin drying, contacting with nitrogen (N₂), air drying, etc.).

At step 110, in some embodiments, the substrate is contacted with the etchant composition. The contacting may comprise applying the etchant composition to the surface by at least one of spraying the etchant composition onto the surface; dipping (in a static or dynamic volume of the etchant composition) the substrate into etchant composition; contacting the surface with another material (e.g., a pad, or fibrous sorbent applicator element, that has etchant composition absorbed thereon); contacting the substrate with an amount of the etchant composition in a circulating pool; submersing the substrate in the etchant composition. or any combination thereof, among other techniques in which the etchant composition is brought into removal contact with the surface of the microelectronic substrate that contains silicon. The application may be in a batch or single wafer apparatus, for dynamic or static cleaning.

The selective etching of silicon nitride using the etchant composition may proceed in the presence of silicon oxide and polysilicon, as mentioned above. In addition to silicon oxide and polysilicon, the selective etching of silicon nitride using the etchant composition may proceed in the presence of other materials, while maintaining selectivity for silicon nitride. Examples of these other materials include, without limitation, at least one of conductive materials, semiconducting materials, insulating materials, processing materials, or any combination thereof. In some embodiments, a metal silicide is present during the selective etching of silicon nitride. In some embodiments, the metal silicide is present but not exposed during the selective etching of silicon nitride.

The conditions of the contacting may comprise at least one of a duration, a temperature, or any combination thereof. The duration should be sufficient to selectively remove the silicon nitride. The duration of exposure to the etchant composition and the temperature of the etchant composition may be selected based on a desired amount of removal of the silicon nitride from a surface of the substrate. The duration of the contacting should balance process control and quality with process efficiency and throughput of the etching process and the semiconductor fabrication line. Examples of a suitable duration may be in a range of 5 minutes to 300 minutes, or any range or subrange therebetween, such as, 10 minutes to 60 minutes. Examples of a suitable temperature is a temperature in a range of 100° C. to 250° C. (e.g., 100° C. to 180° C., 150° C. to 180° C.), or any range or subrange therebetween. Such contacting times and temperatures are illustrative, and other suitable contacting times and temperature conditions may be used herein without departing from this disclosure.

By contacting the substrate with the etchant composition, the etchant composition may passivate at least one of a surface comprising polysilicon, a surface comprising silicon oxide, or any combination thereof. In some embodiments, passivating a surface comprises modifying the surface so as to reduce a reactivity of the surface—for example, when in the presence of substances that etch silicon nitride. In some embodiments, the metal oxidizer, when in a presence of a surface comprising polysilicon, modifies or is configured to modify the surface comprising polysilicon, so as to reduce a reactivity of the surface comprising polysilicon. In some embodiments, the metal oxidizer, when in a presence of a surface comprising silicon oxide, modifies or is configured to modify the surface comprising silicon oxide, so as to reduce a reactivity of the surface comprising silicon oxide. In some embodiments, the etchant composition passivates surfaces other than silicon nitride.

The etchant composition may exhibit a selectivity for silicon nitride relative to polysilicon of at least 150, at least 200, at least 500, at least 1000, at least 2000, at least 4000, or greater. In some embodiments, for example, the etchant composition exhibits a selectivity for silicon nitride relative to polysilicon of 10:1 to 7000:1, or any range or subrange therebetween. The etchant composition may exhibit a selectivity for silicon nitride relative to silicon oxide of at least 150, at least 200, at least 500, at least 1000, at least 2000, at least 4000, or greater. In some embodiments, for example, the etchant composition exhibits a selectivity for silicon nitride relative to silicon oxide of 10:1 to 7000:1, or any range or subrange therebetween. In some embodiments, the etchant composition's selectivity for silicon nitride relative to polysilicon and silicon oxide is the same or similar. In some embodiments, the etchant composition's selectivity for silicon nitride relative to polysilicon and silicon oxide is different.

After contacting the substrate with the etchant composition, excess etchant composition and other substances may be rinsed, washed, or otherwise removed from the surfaces using water (e.g., deionized water) at a temperature in a range of 20° C. to 90° C., or any range or subrange therebetween, followed by drying (e.g., spin drying, contacting with nitrogen (N₂), air drying, etc.).

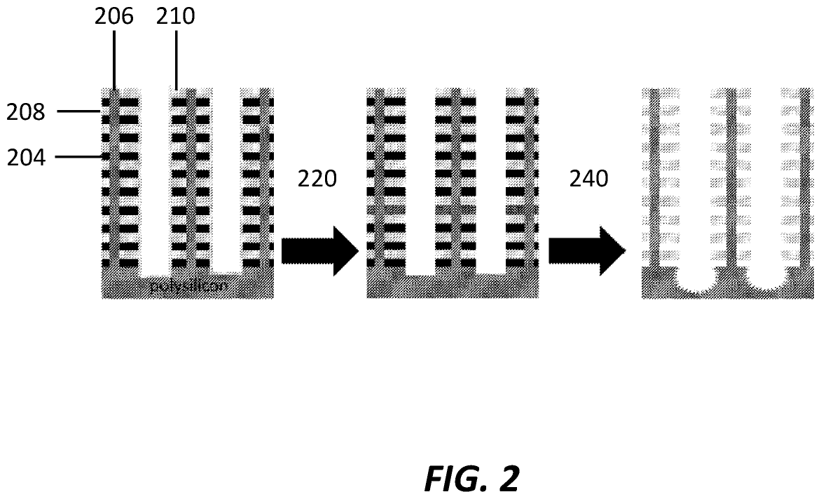

FIG. 2 is a schematic diagram of a method 200 for selective etching of silicon nitride, according to some embodiments. As shown in FIG. 2, in some embodiments, a substrate 202 comprises silicon nitride 204, polysilicon 206, and silicon oxide 208. The substrate 202 also comprises a surface oxide 210. At step 220, the surface oxide 210 is removed. At step 240, the polysilicon 206 is passivated and the silicon nitride 204 is etched, without etching the polysilicon 206 (e.g., the passivated polysilicon) or at least etching less than 5% of the polysilicon 206 surface.

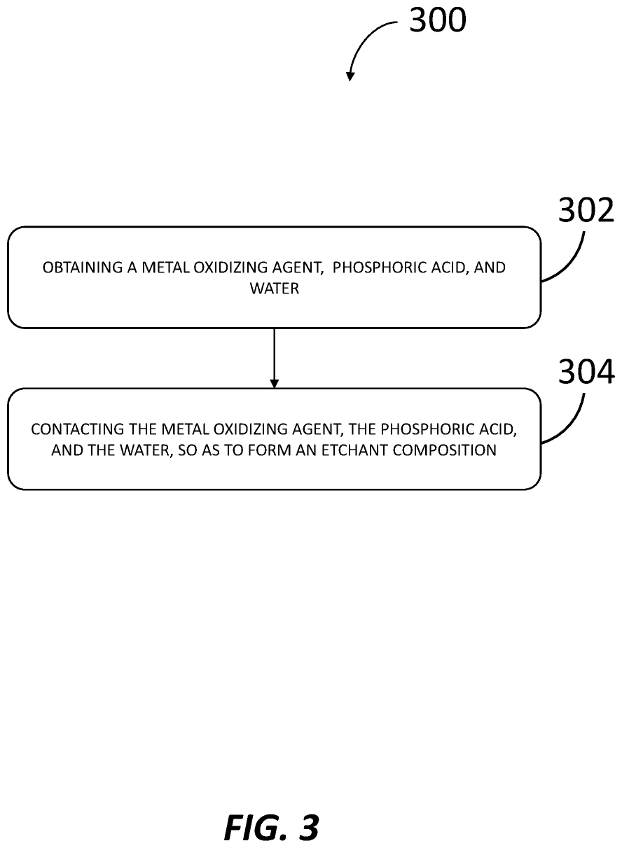

FIG. 3 presents an illustration of a process flow showing a structure with polysiliconat the bottom of a via, while also containing silicon oxide and silicon nitride surfaces. The combined passivation and etching step in accordance with the present disclosure. involves incorporation of Cerium sulfate, Ce(IV) SO₄ into an etchant composition such as Entegris PlanarEX 2155.

FIG. 3 is a flowchart of a method 300 for forming an etchant composition, according to some embodiments. As shown in FIG. 3, in some embodiments, the method 300 for forming an etchant composition comprises at least one of the following steps: a step 302 of obtaining a metal oxidizing agent, phosphoric acid, and water; a step 304 of contacting the metal oxidizing agent, the phosphoric acid, and the water, so as to form an etchant composition; or any combination thereof. In some embodiments, the contacting is performed under heating to a temperature in a range of 20° C. to 200° C., or any range or subrange therebetween. In some embodiments, the contacting comprising mixing, combining, adding, or otherwise bringing into close or immediate proximity so as to form the etchant composition.

It will be appreciated that any of the one or more components disclosed herein may be included in the etchant composition without departing from this disclosure.

### Example 1

### Base Formulation

A base formulation was prepared. The base formulation included about 82% by weight of phosphoric acid, about 14% by weight of water, about 4% by weight of 3-aminopropylsilanetriol, and about 0.1% by weight of tetramethylammonium silicate. The percentage by weight is based on a total weight of the base formulation.

### Example 2

### Comparative Formulation (No Metal Oxidizing Agent)

The base formulation of Example 1 was exposed to a blanket silicon nitride (SiN) film and a phosphorus doped polysilicon film at a temperature of 160° C. The change in thickness of the blanket silicon nitride (SiN) film and the phosphorus doped polysilicon film was measured by spectroscopic ellipsometry. The SiN etch rate and the polysilicon etch rate were calculated from the measured change in thickness over a period of 10 minutes and 120 minutes, respectively. The results are summarized in Table 1 below.

### Example 3

### Formulation A

About 0.1% by weight of phosphomolybdic acid hydrate was added to the base formulation of Example 1 to form Formulation A. Formulation A was exposed to a blanket silicon nitride (SiN) film and a phosphorus doped polysilicon film at a temperature of 160° C. The change in thickness of the blanket silicon nitride (SiN) film and the phosphorus doped polysilicon film was measured by spectroscopic ellipsometry. The SiN etch rate and the polysilicon etch rate were calculated from the measured change in thickness over a period of 10 minutes and 120 minutes, respectively. The results are summarized in Table 1 below. The percentage by weight is based on the total weight of the base formulation.

### Example 4

### Formulation B

About 0.1% by weight of silicomolybdic acid was added to the base formulation of Example 1 to form Formulation B. Formulation B was exposed to a blanket silicon nitride (SiN) film and a phosphorus doped polysilicon film at a temperature of 160° C. The change in thickness of the blanket silicon nitride (SiN) film and the phosphorus doped polysilicon film was measured by spectroscopic ellipsometry. The SiN etch rate and the polysilicon etch rate were calculated from the measured change in thickness over a period of 10 minutes and 120 minutes, respectively. The results are summarized in Table 1 below. The percentage by weight is based on the total weight of the base formulation.

### Example 5

### Formulation C

About 0.1% by weight of molybdenum (VI) oxide was added to the base formulation of Example 1 to form Formulation C. Formulation C was exposed to a blanket silicon nitride (SiN) film and a phosphorus doped polysilicon film at a temperature of 160° C. The change in thickness of the blanket silicon nitride (SiN) film and the phosphorus doped polysilicon film was measured by spectroscopic ellipsometry. The SiN etch rate and the polysilicon etch rate were calculated from the measured change in thickness over a period of 10 minutes and 120 minutes, respectively. The results are summarized in Table 1 below. The percentage by weight is based on the total weight of the base formulation.

### Example 6

### Formulation D

About 0.1% by weight of cerium (IV) sulfate was added to the base formulation of Example 1 to form Formulation D. Formulation D was exposed to a blanket silicon nitride (SiN) film and a phosphorus doped polysilicon film at a temperature of 160° C. The change in thickness of the blanket silicon nitride (SiN) film and the phosphorus doped polysilicon film was measured by spectroscopic ellipsometry. The SiN etch rate and the polysilicon etch rate were calculated from the measured change in thickness over a period of 10 minutes and 120 minutes, respectively. The results are summarized in Table 1 below. The percentage by weight is based on the total weight of the base formulation.

### Example 7

### Formulation E

About 0.05% by weight of cerium (IV) sulfate was added to the base formulation of Example 1 to form Formulation E. Formulation E was exposed to a blanket silicon nitride (SiN) film and a phosphorus doped polysilicon film at a temperature of 160° C. The change in thickness of the blanket silicon nitride (SiN) film and the phosphorus doped polysilicon film was measured by spectroscopic ellipsometry. The SiN etch rate and the polysilicon etch rate were calculated from the measured change in thickness over a period of 10 minutes and 120 minutes, respectively. The results are summarized in Table 1 below. The percentage by weight is based on the total weight of the base formulation.

### Example 8

### Formulation F

About 0.05% by weight of La₂O₃ was added to the base formulation of Example 1 to form Formulation F. Formulation F was exposed to a blanket silicon nitride (SiN) film and a phosphorus doped polysilicon film at a temperature of 160° C. The change in thickness of the blanket silicon nitride (SiN) film and the phosphorus doped polysilicon film was measured by spectroscopic ellipsometry. The SiN etch rate and the polysilicon etch rate were calculated from the measured change in thickness over a period of 10 minutes and 120 minutes, respectively. The results are summarized in Table 1 below. The percentage by weight is based on the total weight of the base formulation.

### Example 9

### Formulation G

About 0.25% by weight of nitric acid was added to the base formulation of Example 1 to form Formulation G. Formulation G was exposed to a blanket silicon nitride (SiN) film and a phosphorus doped polysilicon film at a temperature of 160° C. The change in thickness of the blanket silicon nitride (SiN) film and the phosphorus doped polysilicon film was measured by spectroscopic ellipsometry. The SiN etch rate and the polysilicon etch rate were calculated from the measured change in thickness over a period of 10 minutes and 120 minutes, respectively. The results are summarized in Table 1 below. The percentage by weight is based on the total weight of the base formulation.

TABLE 1
Polysilicon Etch Rate, SiN Etch Rate, and
Selectivity for Formulations A-G

| | Polysilicon | SiN | |
|---|---|---|---|
| | Etch Rate | Etch Rate | Selectivity |
| Formulation | (Å/min) | (Å/min) | (SiN/Polysilicon) |
| Comparative | 4.1 | 135 | 33 |
| A | 0.16 | 135 | 844 |
| B | 0.13 | 133 | 1023 |
| C | 0.13 | 131 | 1008 |
| D | 0.15 | 138 | 920 |
| E | 0.13 | 135 | 1038 |
| F | 3.2 | 138 | 43 |
| G | 2.2 | 133 | 60 |

### ASPECTS

Various Aspects are described below. It is to be understood that any one or more of the features recited in the following Aspect(s) can be combined with any one or more other Aspect(s).

Aspect 1. An etchant composition comprising:
at least 60% by weight of phosphoric acid based on a total weight of the etchant composition;
at least 1% by weight of water based on the total weight of the etchant composition; and
no greater than 2% by weight of a metal oxidizer based on the total weight of the etchant composition,
   wherein the metal oxidizer, when in a presence of a surface comprising polysilicon, is configured to modify the surface comprising polysilicon, so as to reduce a reactivity of the surface comprising polysilicon with the phosphoric acid.

Aspect 2. The etchant composition according to Aspect 1, wherein the etchant composition comprises: 80% to 95% by weight of the phosphoric acid based on the total weight of the etchant composition.

Aspect 3. The etchant composition according to any one of Aspects 1-2, wherein the etchant composition comprises: 1% to 25% by weight of the water based on the total weight of the etchant composition.

Aspect 4. The etchant composition according to any one of Aspects 1-3, wherein the etchant composition comprises:
0.001% to 1% by weight of the metal oxidizer based on the total weight of the etchant composition.

Aspect 5. The etchant composition according to any one of Aspects 1-4, wherein the etchant composition comprises:
0.001% to 0.1% by weight of the metal oxidizer based on the total weight of the etchant composition.

Aspect 6. The etchant composition according to any one of Aspects 1-5, wherein the metal oxidizer comprises a cation of at least one of Sc, Ti, V, Cr, Mn, Fe, Co, Ni, Cu, Zn, Y, Zr, Nb, Mo, Tc, Ru, Rh, Pd, Ag, Cd, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Ac, Th, Pa, U, Np, Pu, Am, Cm, Bk, Cf, Es, Fm, Md, No, Lr, Rf, Db, Sg, Bh, Hs, Mt, Ds, Rg, Cn, or any combination thereof.

Aspect 7. The etchant composition according to any one of Aspects 1-6, wherein the metal oxidizer is at least one of Ce⁺³, Ce⁺⁴, V⁺², V⁺³, V⁺⁴, V⁺⁵, Mo⁺², Mo⁺³, Mo⁺⁴, Mo⁺⁵, Mo⁺⁶, or any combination thereof.

Aspect 8. The etchant composition according to any one of Aspects 1-7, wherein the metal oxidizer is a dissolution product of a metal oxidizing agent.

Aspect 9. The etchant composition according to Aspect 8, wherein the metal oxidizing agent comprises at least one of titanium (IV) oxysulfate, titanium (IV) sulfate hydrate, phosphomolybdic acid hydrate, silicomolybdic acid, molybdenum (VI) oxide, molybdic acid, lanthanum oxide, cerium (IV) sulfate, ceric ammonium nitrate, phosphotungstic acid, vanadium pentaoxide, cobalt (Ill) acetylacetonate, or any combination thereof.

Aspect 10. The etchant composition according to any one of Aspects 1-8, further comprising at least one of a fluoride compound, a silicon-containing compound, an alkylbenzenesulfonic acid, an alkyldiphenyl oxide disulfonic acid, a pyridine compound, or any combination thereof.

Aspect 11. The etchant composition according to any one of Aspects 1-9, wherein the etchant composition exhibits a selectivity for silicon nitride relative to polysilicon in a range of 10:1 to 7000:1.

Aspect 12. A method comprising:
obtaining a substrate, the substrate comprising:
   a surface comprising silicon nitride,
   a surface comprising silicon oxide, and
   a surface comprising polysilicon;
obtaining an etchant composition, the etchant composition comprising:
   at least 60% by weight of phosphoric acid based on a total weight of the etchant composition;
   at least 1% by weight of water based on the total weight of the etchant composition; and
   no greater than 2% by weight of a metal oxidizer based on the total weight of the etchant composition;
contacting the substrate with the etchant composition,
   wherein the etchant composition removes at least a portion of the surface comprising silicon nitride,
   wherein the etchant composition removes less than 5% of the surface comprising polysilicon.

Aspect 13. The method according to Aspect 12, wherein the etchant composition comprises: 80% to 95% by weight of the phosphoric acid based on the total weight of the etchant composition.

Aspect 14. The method according to any one of Aspects 12-13, wherein the etchant composition comprises: 1% to 25% by weight of the water based on the total weight of the etchant composition.

Aspect 15. The method according to any one of Aspects 12-14, wherein the etchant composition comprises: 0.001% to 1% by weight of the metal oxidizer based on the total weight of the etchant composition.

Aspect 16. The method according to any one of Aspects 12-15, wherein the etchant composition comprises: 0.001% to 0.1% by weight of the metal oxidizer based on the total weight of the etchant composition.

Aspect 17. The method according to any one of Aspects 12-16, wherein the metal oxidizer comprises a cation of at least one of Sc, Ti, V, Cr, Mn, Fe, Co, Ni, Cu, Zn, Y, Zr, Nb, Mo, Tc, Ru, Rh, Pd, Ag, Cd, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Ac, Th, Pa, U, Np, Pu, Am, Cm, Bk, Cf, Es, Fm, Md, No, Lr, Rf, Db, Sg, Bh, Hs, Mt, Ds, Rg, Cn, or any combination thereof.

Aspect 18. The method according to any one of Aspects 12-17, wherein the etchant composition further comprises at least one of a fluoride compound, a silicon-containing compound, an alkylbenzenesulfonic acid, an alkyldiphenyl oxide disulfonic acid, a pyridine compound, or any combination thereof.

Aspect 19. The method according to any one of Aspects 12-18, wherein the etchant composition exhibits a selectivity for silicon nitride relative to polysilicon in a range of 10:1 to 7000:1.

Aspect 20. A method comprising:
obtaining phosphoric acid;
obtaining water;
obtaining a metal oxidizing agent;
contacting the phosphoric acid, the water, and the metal oxidizing agent, so as to form an etchant composition, the etchant composition comprising:
   at least 60% by weight of phosphoric acid based on a total weight of the etchant composition;
   at least 1% by weight of water based on the total weight of the etchant composition; and
   no greater than 2% by weight of a metal oxidizer based on the total weight of the etchant composition,
      wherein the metal oxidizer, when in a presence of a surface comprising polysilicon, is configured to modify the surface comprising polysilicon, so as to reduce a reactivity of the surface comprising polysilicon with the phosphoric acid.

What is claimed is:

1. An etchant composition comprising:
at least 60% by weight of phosphoric acid based on a total weight of the etchant composition;
at least 1% by weight of water based on the total weight of the etchant composition; and
no greater than 2% by weight of a metal oxidizer based on the total weight of the etchant composition,
wherein the metal oxidizer, when in a presence of a surface comprising polysilicon, is configured to modify the surface comprising polysilicon, so as to reduce a reactivity of the surface comprising polysilicon with the phosphoric acid.

2. The etchant composition of claim 1, wherein the etchant composition comprises:
80% to 95% by weight of the phosphoric acid based on the total weight of the etchant composition.

3. The etchant composition of claim 1, wherein the etchant composition comprises:
1% to 25% by weight of the water based on the total weight of the etchant composition.

4. The etchant composition of claim 1, wherein the etchant composition comprises:
0.001% to 1% by weight of the metal oxidizer based on the total weight of the etchant composition.

5. The etchant composition of claim 1, wherein the etchant composition comprises:
0.001% to 0.1% by weight of the metal oxidizer based on the total weight of the etchant composition.

6. The etchant composition of claim 1, wherein the metal oxidizer comprises a cation of at least one of Sc, Ti, V, Cr, Mn, Fe, Co, Ni, Cu, Zn, Y, Zr, Nb, Mo, Tc, Ru, Rh, Pd, Ag, Cd, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Ac, Th, Pa, U, Np, Pu, Am, Cm, Bk, Cf, Es, Fm, Md, No, Lr, Rf, Db, Sg, Bh, Hs, Mt, Ds, Rg, Cn, or any combination thereof.

7. The etchant composition of claim 1, wherein the metal oxidizer is at least one of Ce⁺³, Ce⁺⁴, V⁺², V⁺³, V⁺⁴, V⁺⁵, Mo⁺², Mo⁺³, Mo⁺⁴, Mo⁺⁵, Mo⁺⁶, or any combination thereof.

8. The etchant composition of claim 1, wherein the metal oxidizer is a dissolution product of a metal oxidizing agent.

9. The etchant composition of claim 8, wherein the metal oxidizing agent comprises at least one of titanium (IV) oxysulfate, titanium (IV) sulfate hydrate, phosphomolybdic acid hydrate, silicomolybdic acid, molybdenum (VI) oxide, molybdic acid, lanthanum oxide, cerium (IV) sulfate, ceric ammonium nitrate, phosphotungstic acid, vanadium pentaoxide, cobalt (III) acetylacetonate, or any combination thereof.

10. The etchant composition of claim 1, further comprising at least one of a fluoride compound, a silicon-containing compound, an alkylbenzenesulfonic acid, an alkyldiphenyl oxide disulfonic acid, a pyridine compound, or any combination thereof.

11. The etchant composition of claim 1, wherein the etchant composition exhibits a selectivity for silicon nitride relative to polysilicon in a range of 10:1 to 7000:1.

12. A method comprising:
obtaining a substrate, the substrate comprising:
a surface comprising silicon nitride,
a surface comprising silicon oxide, and
a surface comprising polysilicon;
obtaining an etchant composition, the etchant composition comprising:
at least 60% by weight of phosphoric acid based on a total weight of the etchant composition;
at least 1% by weight of water based on the total weight of the etchant composition; and
no greater than 2% by weight of a metal oxidizer based on the total weight of the etchant composition;
contacting the substrate with the etchant composition,
wherein the etchant composition removes at least a portion of the surface comprising silicon nitride,
wherein the etchant composition removes less than 5% of the surface comprising polysilicon.

13. The method of claim 12, wherein the etchant composition comprises:
80% to 95% by weight of the phosphoric acid based on the total weight of the etchant composition.

14. The method of claim 12, wherein the etchant composition comprises:
1% to 25% by weight of the water based on the total weight of the etchant composition.

15. The method of claim 12, wherein the etchant composition comprises:
0.001% to 1% by weight of the metal oxidizer based on the total weight of the etchant composition.

16. The method of claim 12, wherein the etchant composition comprises:
0.001% to 0.1% by weight of the metal oxidizer based on the total weight of the etchant composition.

17. The method of claim 12, wherein the metal oxidizer comprises a cation of at least one of Sc, Ti, V, Cr, Mn, Fe, Co, Ni, Cu, Zn, Y, Zr, Nb, Mo, Tc, Ru, Rh, Pd, Ag, Cd, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Ac, Th, Pa, U, Np, Pu, Am, Cm, Bk, Cf, Es, Fm, Md, No, Lr, Rf, Db, Sg, Bh, Hs, Mt, Ds, Rg, Cn, or any combination thereof.

18. The method of claim 12, wherein the etchant composition further comprises at least one of a fluoride compound, a silicon-containing compound, an alkylbenzenesulfonic acid, an alkyldiphenyl oxide disulfonic acid, a pyridine compound, or any combination thereof.

19. The method of claim 12, wherein the etchant composition exhibits a selectivity for silicon nitride relative to polysilicon in a range of 10:1 to 7000:1.

20. A method comprising:
obtaining phosphoric acid;
obtaining water;
obtaining a metal oxidizing agent;
contacting the phosphoric acid, the water, and the metal oxidizing agent, so as to form an etchant composition, the etchant composition comprising:
at least 60% by weight of phosphoric acid based on a total weight of the etchant composition;
at least 1% by weight of water based on the total weight of the etchant composition; and
no greater than 2% by weight of a metal oxidizer based on the total weight of the etchant composition,
wherein the metal oxidizer, when in a presence of a surface comprising polysilicon, is configured to modify the surface comprising polysilicon, so as to reduce a reactivity of the surface comprising polysilicon with the phosphoric acid.
